(19) United States
(12) Patent Application Publication
(10) Pub. No.: US 2003/0030066 A1
(43) Pub. Date: Feb. 13, 2003

(54) Optical device

(75) Inventor: Edmund Peter Clinton Herman, (US)

Correspondence Address: DALLAS OFFICE OF FULBRIGHT & JAWORSKI L.L.P., 2200 ROSS AVENUE, SUITE 2800, DALLAS, TX, 75201-2784, US

(73) Assignee: Bookham Technology PLC, Abingdon (GB)

(21) Appl. No.: 10/216,095

(22) Filed: Aug. 9, 2002

(30) Foreign Application Priority Data
Aug. 10, 2001 (GB) 0119585.8

(51) Int. Cl. H01L 33/00

(52) U.S. Cl. 257/100

(57) ABSTRACT

An optical device (110) has a substrate (101) with an outer surface (103) and an optical component (117) having a base (115) which interfaces with the outer surface of the substrate. In one embodiment at least one gap (109) is disposed between the outer surface of the substrate and the base of the optical device, the at least one gap containing an adhesive (125) which adheres the substrate and the optical device together and at least one interface (123,133) between the base and the outer surface. In another embodiment a plurality of spaced-apart gaps are disposed between the outer surface of the substrate and the base of the optical device, each gap containing an adhesive which adheres the substrate and optical device together.

### FIELD OF THE INVENTION

The present invention relates to an optical device having a substrate with an outer surface and an optical component having a base which interfaces with, and is adhered to, the outer surface of the substrate. The present invention is particularly, but not exclusively, concerned with the case where the optical component is a laser diode.

### BACKGROUND OF THE INVENTION

A previously known way of mounting a laser diode to a substrate is shown in FIGS. 1-3. In FIGS. 1-3 there is shown a fragment of an optical transceiver or transmitter 10 having a substrate 1 with an upper surface 3. The substrate 1 has a silicon body 5 which is overlaid with a surface layer 7 of silicon dioxide and/or silicon nitride at the upper surface 3. A recess 9 is formed in the upper surface 3 of the substrate 1. The recess 9 is formed by firstly etching the silicon body 5 using a silicon dioxide mask and then depositing the surface layer 7 on the etched silicon body 5. Preferably, the etching process is anisotropic so as to provide the recess 9 with vertical side walls 13. Isotropic etching could, of course, be used instead. The side walls 13 could also be etched so as to be sloped. As an example, a dry etching process may be used such as plasma etching.

As shown particularly well in FIG. 2, the width w1 of the recess 9 is smaller than the width w2 of a base 15 of a laser diode 17. This allows the laser diode 17 to be mounted on the upper surface 3 of the substrate 1 so as to straddle the recess 9. In this way, the surface layer 7 adjacent the recess 9 acts as a plinth 19 for supporting the overhanging or outer edge region 21 of the laser diode base 15. Mounting the laser diode 17 on the surface layer 7 isolates the laser diode 17 from the conductive silicon body 5 to prevent shorting.

The width w1 of the recess 9 is typically about 200-300 μm and the width w2 of the laser diode 15 is typically about 5-10 μm greater than w1. If the laser diode 17 is mounted centrally over the recess 9, the laser diode base 15 extends several microns on either side of the recess 9.

Disposed in the recess 9 underneath a central or inner region 23 of the laser diode base 15 is a solder preform 25. Heating of the solder preform 25 results in a solder joint being formed between the inner region 23 of the laser diode base 15 and a bottom or base 27 of the recess 9 thereby fixedly securing the laser diode 17 to the substrate 1.

Although this arrangement of mounting a laser diode 17 to a substrate 1 is satisfactory, it could be improved. As an example, the laser diode 17 experiences a relatively large bending force due to the compressive nature of the solder joint. This can lead to weaknesses in the solder joint which may be exacerbated by crack or defect propagation on temperature cycling. The laser diode 17 and its metallized electrical contacts are also subjected to stresses by the solder joint.

The present invention proposes to provide an improved arrangement of mounting an optical device to a substrate.

### SUMMARY OF THE INVENTION

According to the present invention there is provided an optical device having a substrate with an outer surface and an optical component having a base which interfaces with the outer surface of the substrate, provided that either:

a) at least one gap is disposed between the outer surface of the substrate and the base of the optical device, the at least one gap containing an adhesive which adheres the substrate and optical device together and at least one interface between the base and the outer surface, or

(b) a plurality of spaced-apart gaps are disposed between the outer surface of the substrate and the base of the optical device, each gap containing an adhesive which adheres the substrate and optical device together.

Preferred features of the present invention are set forth in the subsidiary claims appended hereto.

By way of example, embodiments of the present invention will now be described with reference to the accompanying FIGURES of drawings.

### BRIEF DESCRIPTION OF THE FIGURES OF DRAWINGS

FIG. 1 is a schematic, scrap front perspective view of a prior art optical transceiver/transmitter having a recessed substrate on which a laser diode is mounted;

FIG. 2 is a schematic, scrap front view of the optical transceiver/transmitter of FIG. 1;

FIG. 3 is a schematic, scrap front perspective view of the recessed substrate in FIG. 1;

FIG. 4 is an exploded, schematic, scrap front perspective view of an optical transceiver/transmitter in accordance with the present invention having a recessed substrate and a laser diode;

FIG. 5 is a schematic, scrap front view of the optical transceiver/transmitter of FIG. 4 with the laser diode mounted on the substrate;

FIG. 6 is a schematic, scrap plan view of the recess of the substrate of FIG. 4 with an alternative solder pattern therein;

FIG. 7 is a schematic, scrap front view of the substrate of FIG. 4 with an alternative recess;

FIG. 8A is a schematic, scrap plan view of the substrate of FIG. 4 with another alternative recess; and

FIG. 8B is a schematic, scrap plan view of the substrate of FIG. 4 with a yet further alternative recess.

### DETAILED DESCRIPTION OF THE EXEMPLARY EMBODIMENTS OF THE INVENTION

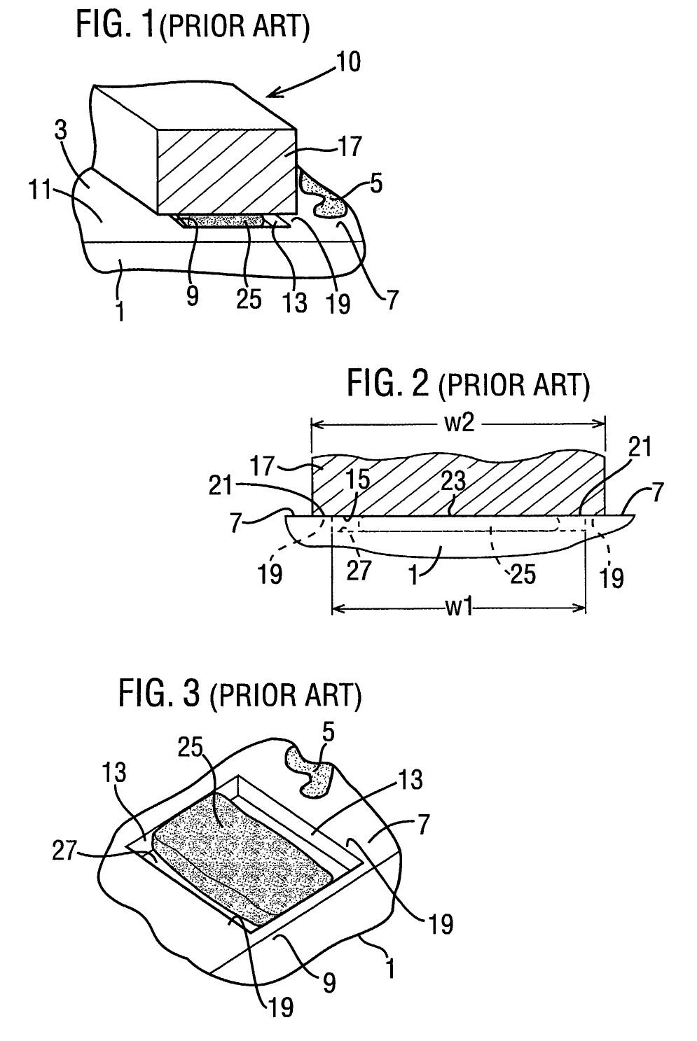

There now follows a detailed description of several embodiments of an optical transceiver or transmitter in accordance with the present invention. For simplicity, those features of the optical transceiver/transmitter in accordance with the present invention which correspond to features of the prior art optical transceiver/transmitter 10 described with reference to FIGS. 1-3 have been assigned like reference numerals.

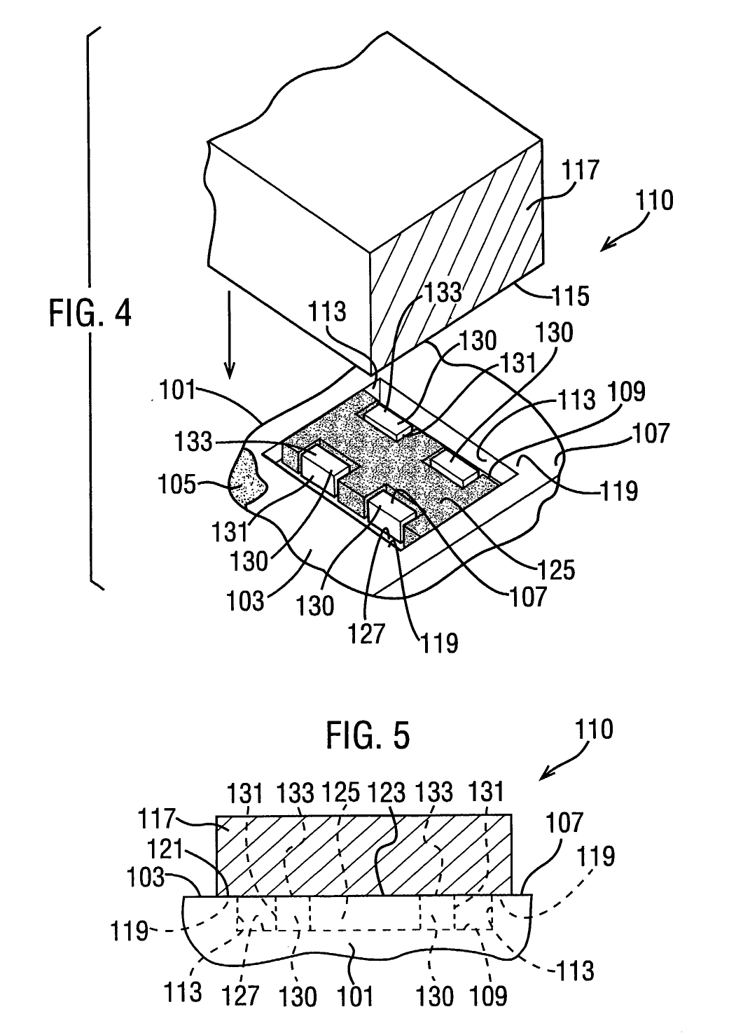

In FIGS. 4 and 5 there is shown an exploded fragmentary view of an optical transceiver/transmitter 110 in accordance with the present invention which comprises a substrate 101 having a body 105 of silicon and a surface layer 107 of silicon dioxide and/or silicon nitride at an upper face 103 of the substrate 101. As before, a recess 109 is etched in the substrate 101 to have the same dimensions as described previously with reference to FIGS. 1-3.

The etching technique for the recess 109 is as described for FIGS. 1-3 except that the pattern of the mask used for the selective etching of the silicon body 105 is such that a number of substantially identical silicon pillars 130 are formed in spaced apart relation in the recess 109. The pillars 130 are then coated with the silicon dioxide surface layer 107 together with the rest of the silicon body 105. Each pillar 130 has vertical side faces 131 and an upper face 133 co-planar with the upper face 103 of the substrate 101 adjacent the recess 109. The side faces 131 could, of course, be sloped instead, if desired.

The pillars 130 in the recess 109 provide additional support for the laser diode 117, specifically support for the inner region 123 of the laser diode base 115, as shown in FIG. 5. By supporting the laser diode base 115 both at its outer edge region 121 with the plinths 119 and its inner region 123 with the pillars 130, the bending moment on the laser diode 117 is reduced compared to the case of the laser diode 117 straddling the recess 109 without intermediate support, as in the prior art arrangement shown in FIGS. 1-3.

The surface layer 107 may be formed by firstly depositing a coating of silicon dioxide and then depositing a silicon nitride coating onto the silicon dioxide. The nitride layer would act in concert with the silicon dioxide to isolate the laser diode 117 from the silicon body 105 whilst providing the substrate 101 with an antireflective surface.

To enable the dimensions of the recess 109 to be the same as in the prior art arrangement shown in FIGS. 1-3 without a significant loss of joint surface area resulting from the presence of the pillars 130, a solder preform 125 is plated to the base 127 of the recess 109 about and between the pillars 130. The application of the soldered preform 125 by plating allows the preform 125 to be shaped to the surface area of the base 127 of the recess 109, as shown in FIG. 4. Accordingly, the surface area of the solder joint is not significantly reduced by the provision of the pillars 130.

The preferred method for plating the solder preform 125 is electroplating. Preferably, the solder preform 125 plated into the recess 109 is a multi-layer gold-tin eutectic solder. A multi-layer gold-tin eutectic solder 125 is deposited in the recess 109 of the substrate 101 by electroplating by firstly depositing a seed layer (not shown) for the solder preform 125 into the recess 109. Preferably, the seed layer is a layer having a gold upper surface, e.g. by using a single gold layer for the seed layer or a multi-component layer with the gold uppermost such as in a titanium-tungsten-gold layer. After depositing the seed layer, the shape of the area of the base 127 of the recess 109 to be plated is defined by a photoresist. The multi-layer solder preform 125 is built up in the recess 109 by sequentially electroplating layers of gold and tin to the thickness required and then a top layer of gold.

After the solder preform 125 has been plated into the recess 109, the photoresist is removed and the laser diode 117 mounted centrally over the recess 109 so that the outer edge region 121 of the laser diode base 115 is supported on the plinth 119 and the inner region 123 is supported on the pillars 130. The solder preform 125 is then fused to create a solder joint between the laser diode base 115 and the bottom 127 of the substrate recess 109. In this regard, the solder preform 125 stands proud of the upper surface 103. The laser diode 117 is pushed down on the preform 125 and as the preform 125 contracts on heating it pulls down the laser diode 117.

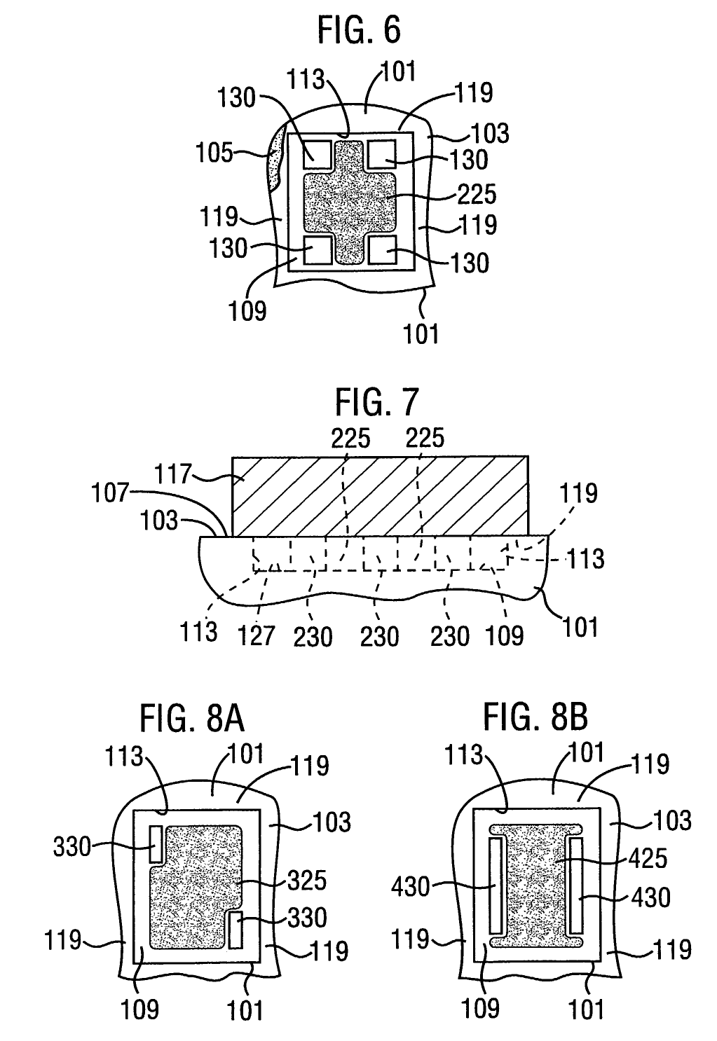

As will be appreciated by the skilled reader in the art, the pattern of the plated solder preform 125 in the recess 109 of the substrate 101 can take on many different forms with electroplating allowing a resolution of approximately ±10 μm. For instance, FIG. 6 shows an alternative shape for a plated solder preform 225 for use in the recess 109 shown in FIGS. 4 and 5.

It will further be appreciated that the number of the pillars 130 and their arrangement and dimensions can be varied widely. Non-limiting examples of alternative pillars 230, 330, 430 are illustrated in FIGS. 7, 8A and 8B. FIGS. 8A and 8B also show examples of possible patterns for a plated solder preform 325, 425 for accommodating the pillars 330, 430.

In a preferred embodiment of the present invention, the pillars 130, 230, 330, 430 are arranged in the recess 109 so that they are not located directly under the laser stripe (not shown) of the laser diode 117.

As will be seen, the embodiments of the present invention herein described provide improved laser diode support. Not only is the bending moment on the laser diode 117 reduced, the solder joint between the laser diode 117 and the substrate 101 is more stable over temperature cycling. By plating the solder preform 125, the recess 109 is able to accommodate the inclusion of the support pillars 130 without an appreciable loss in the solder joint area. Thus, the solder joint between the laser diode 117 and the substrate 101 is equally secure as in the prior art arrangement of FIGS. 1-3 whilst enabling additional support to be provided under the laser diode 117.

As will be understood by the skilled reader in the art, the present invention is not restricted to the exemplary embodiments described above with reference to FIGS. 4-8. Rather, the invention can be varied in many different ways and adopt various other guises within the scope of the appended claims. For instance, the present invention is not restricted to the mounting of a laser diode. The principles outlined herein can be used for mounting various other optical components, for example other light sources, optoelectronic components such as those which produce photocurrent (e.g. a photodiode) etc. Moreover, the recess arrangements described above with reference to FIGS. 4-8 could be inverted so that recesses are formed in place of the pillars and a wall network replaces the recess. The wall structure would support the inner region of the base of the optical component with a solder preform being plated into the spaced-apart recesses.

Finally, the use of reference numerals from the FIGURES of drawings in the appended claims is purely for illustration and not to be taken as having a limiting effect on the scope of the claims.

1. An optical device (110) having a substrate (101) with an outer surface (103) and an optical component (117) having a base (115) which interfaces with the outer surface of the substrate, wherein either:
(a) at least one gap (109) is disposed between the outer surface of the substrate and the base of the optical device, the at least one gap containing an adhesive (125) which adheres the substrate and optical device together and at least one interface (123,133) between the base and the outer surface, or
(b) a plurality of spaced-apart gaps are disposed between the outer surface of the substrate and the base of the optical device, each gap containing an adhesive which adheres the substrate and optical device together.

2. An optical device according to claim 1, wherein each gap comprises a recess (109) in the outer surface of the substrate and/or a recess in the base of the optical device.

3. An optical device according to claim 1, wherein the at least one interface in the at least one gap is formed with a projecting area (130) of the outer surface and/or the base.

4. An optical device according to claim 1, wherein each gap comprises a recess (109) in the outer surface of the substrate and/or a recess in the base of the optical device, the at least one interface in the at least one gap is formed with a projecting area (130) of the outer surface and/or the base and wherein each projecting area is a support pillar (130) projecting from a bottom (127) of the recess.

5. An optical device according to claim 1, wherein the at least one gap comprises a recess (109) in the outer surface (103) of the substrate (101) and the at least one interface is between a support pillar (130) projecting from a bottom (127) of the recess and the base of the optical device.

6. An optical device according to claim 5, wherein a plurality of spaced-apart support pillars are located on the bottom of the recess.

7. An optical device according to claim 6, wherein the support pillars are regularly arranged in the recess.

8. An optical device according to claim 1, wherein the adhesive is a solder.

9. An optical device according to claim 4, wherein the adhesive has a shape which is complementary to the shape of the bottom of the recess.

10. An optical device according to claim 1, wherein the optical component is an optoelectronic component.

11. An optical device according to claim 1, wherein the optical component is a light source.

12. An optical device according to claim 1, wherein the optical component is selected from the group consisting of a laser diode and a photodiode.

13. An optical device according to claim 1, wherein at least that part of the outer surface of the substrate which interfaces with the base of the optical device is formed by an electrical insulator material.

14. An optical device according to claim 13, wherein the insulator material forms a layer (107) on a semiconductor material (105).

15. An optical device according to claim 1, wherein the base of the optical device has an outer peripheral region (21) and an inner region (23) and wherein the or each gap is formed between the outer surface of the substrate and the inner region of the base of the optical device.

16. An optical device according to claim 15, wherein the outer peripheral region of the base of the optical device interfaces with the outer surface of the substrate.

17. An optical device according to claim 1, wherein the spaced-apart gaps are spaced apart by an interface between the base of the optical device and the outer surface of the substrate.

18. An optical chip (110) in the form of an optical device according to claim 1.
